(19) United States
(12) Patent Application Publication
(10) Pub. No.: US 2007/0096012 A1
(43) Pub. Date: May 3, 2007

(54) Vehicle Service System Digital Camera Interface

(75) Inventor: David A. Voeller, St. Louis, MO (US)

Correspondence Address: POLSTER, LIEDER, WOODRUFF & LUCCHESI, 12412 POWERSCOURT DRIVE SUITE 200, ST. LOUIS, MO, 63131-3615, US

(73) Assignee: HUNTER ENGINEERING COMPANY, Bridgeton, MO (US)

(21) Appl. No.: 11/555,471

(22) Filed: Nov. 1, 2006

Related U.S. Application Data
(60) Provisional application No. 60/732,472, filed on Nov. 2, 2005.

(51) Int. Cl. H01L 27/00

(52) U.S. Cl. 250/208.1

(57) ABSTRACT

A machine-vision vehicle wheel alignment system configured with a high-speed communications network and protocol for communicating data between one or more imaging sensors and at least one system processor.

### CROSS-REFERENCE TO RELATED APPLICATIONS

The present application is related to, and claims priority from, U.S. Provisional Application Serial No. 60/732,472 filed on Nov. 2, 2005, which is herein incorporated by reference.

### STATEMENT REGARDING FEDERALLY SPONSORED RESEARCH

Not Applicable.

### BACKGROUND OF THE INVENTION

The present application is related to vehicle service systems, such as vehicle wheel alignment systems, which utilize imaging sensors to acquire images associated with a vehicle undergoing an inspection or service, and in particular, to an improved system for communicating data from one or more imaging sensors to a vehicle service system processor.

Vehicle service systems, such as machine-vision wheel alignment systems, which utilize imaging sensors often need to communicate a large amount of data between the imaging sensors and the system processors where at least a portion of the image analysis takes place. Cable systems linking the imaging sensors to the system processors typically consist of Universal Serial Bus (USB) version 2.0 connections, IEEE 1394 (Firewire) connections, or Camera Link connections, each of which is capable of communicating large amounts of image data at a high rate of speed. However, each of these cable systems has inherent limitations which restrict the operation of the vehicle service systems. For example, USB 2.0 cables are restricted to a 5.0 meter length unless USB nodes, such as a hub, are utilized. Camera Link connections require specialized interconnection cables between the imaging sensors and system processors, and require expensive image frame capture hardware associated with the system processors. Generally, current cable systems linking imaging sensors with system processors are not expandable or networkable to enable the imaging sensors to communicate with multiple system processors using conventional network connections.

Conventional computer networks, such as Ethernet, can be utilized to facilitate networked data communication between a vehicle service system and one or more imaging sensors, as shown in U.S. Published Patent Application No. 2005-0126021 to Robb et al. However, conventional computer networks are not optimized for the high bandwidth and fast data transmission speeds required for vehicle service image processing applications.

In some vehicle service systems, image processing is handled directly at the individual imaging sensors, and accordingly a reduced amount of image data must be communicated to the system processor over the interconnecting cables or communication links. These types of vehicle service systems can employ lower bandwidth cable systems, such as simple RS-232 serial cables, to connect the imaging sensors to the system processors. However, these types of vehicle service systems are likely to be unable to acquire sufficient amounts of image data for advanced vehicle service procedures which require large numbers of images to be captured in a very short period of time, such as during the steering movement of a vehicle wheel.

With the expanding growth of networked processing systems, it would be advantageous to provide a vehicle service system, such as a machine-vision vehicle wheel alignment system, which employs one or more imaging sensors, with a system for communicating data between the imaging sensors and the system processor which provides a networkable, standardized, and reliable high-bandwidth connection. It would be further advantageous for the communication system to be backward compatible with slower networked communication standards, suitable for latency-sensitive traffic, have dedicated full-duplex connectivity to eliminate bandwidth sharing between links, and which is capable of spanning large physical distances without suffering significant signal or bandwidth degradation.

### BRIEF SUMMARY OF THE INVENTION

Briefly stated, the present disclosure provides a machine-vision vehicle wheel alignment system with a communication system adapted for communicating data between one or more imaging sensors and at least one system processor. The communication system is networkable, standardized, and provides a reliable high bandwidth connection. The communication system is backward compatible with slower communication standards, suitable for latency-sensitive traffic, and provides dedicated full-duplex connectivity to eliminate bandwidth sharing between links. Cable connections utilized by the communication system are capable of spanning large physical distances without requiring repeaters or suffering significant signal degradation.

An embodiment of the present disclosure provides a machine-vision vehicle wheel alignment system configured to utilize a Gigabit Ethernet Vision (GigE Vision) interface standard for communicating data between one or more imaging sensors and at least one system processor. The machine-vision vehicle wheel alignment system is enabled with a GigE Vision interface standard to configure imaging sensors and specify data stream channels, and to allow the imaging sensors to notify software applications when specific events occur. While a single application at the machine-vision vehicle wheel alignment system controls the imaging sensors, multiple applications can monitor the imaging sensors.

An embodiment of the present disclosure provides a machine-vision vehicle wheel alignment system with an operating system driver architecture implementing Receive-Side Scaling (RSS) for scaling data packet communication between at least one imaging sensor and a variable number of system processors.

The foregoing features and advantages of the present disclosure as well as presently preferred embodiments thereof will become more apparent from the reading of the following description in connection with the accompanying drawings.

### BRIEF DESCRIPTION OF THE SEVERAL VIEWS OF THE DRAWINGS

In the accompanying drawings which form part of the specification:

FIG. 1 is a prior art illustration of a single camera medical system configured to send data to a plurality of processors for distributed processing;

FIG. 2 is a prior art illustration of multiple cameras on an assembly line system configured to send data to a plurality of processors for distributed processing;

FIG. 3 is an illustration of a vehicle wheel alignment system configured with a pair of imaging sensors coupled via high-speed communications link to a processing unit;

FIG. 4 is an illustration of a vehicle wheel alignment system configured with eight imaging sensors coupled via a high-speed communications link to a processing unit;

FIG. 5 is an illustration of a vehicle wheel alignment system configured with eight imaging sensors coupled via a high-speed communications link to a processing system having multiple processors;

FIG. 6 is an illustration of a vehicle wheel alignment system configured with a pair of imaging sensors coupled via a high-speed communications link to multiple processing units; and

FIG. 7 is an illustration of a vehicle wheel alignment system configured with a pair of imaging sensors coupled via a high-speed communications link to the Internet for remote monitoring and to a processing unit.

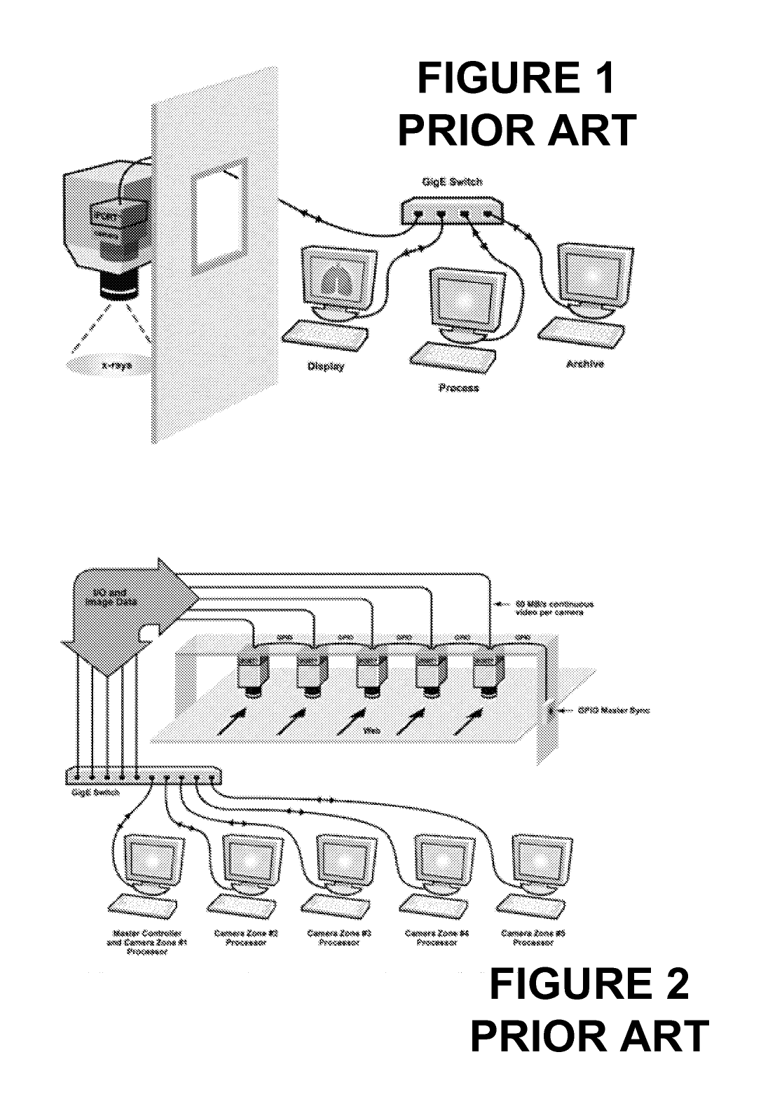

Corresponding reference numerals indicate corresponding parts throughout the several figures of the drawings. It is to be understood that the drawings are for illustrating the concepts of the invention and are not to scale.

### DESCRIPTION OF THE PREFERRED EMBODIMENT

The following detailed description illustrates the invention by way of example and not by way of limitation. The description enables one skilled in the art to make and use the invention, and describes several embodiments, adaptations, variations, alternatives, and uses of the invention, including what is presently believed to be the best mode of carrying out the invention.

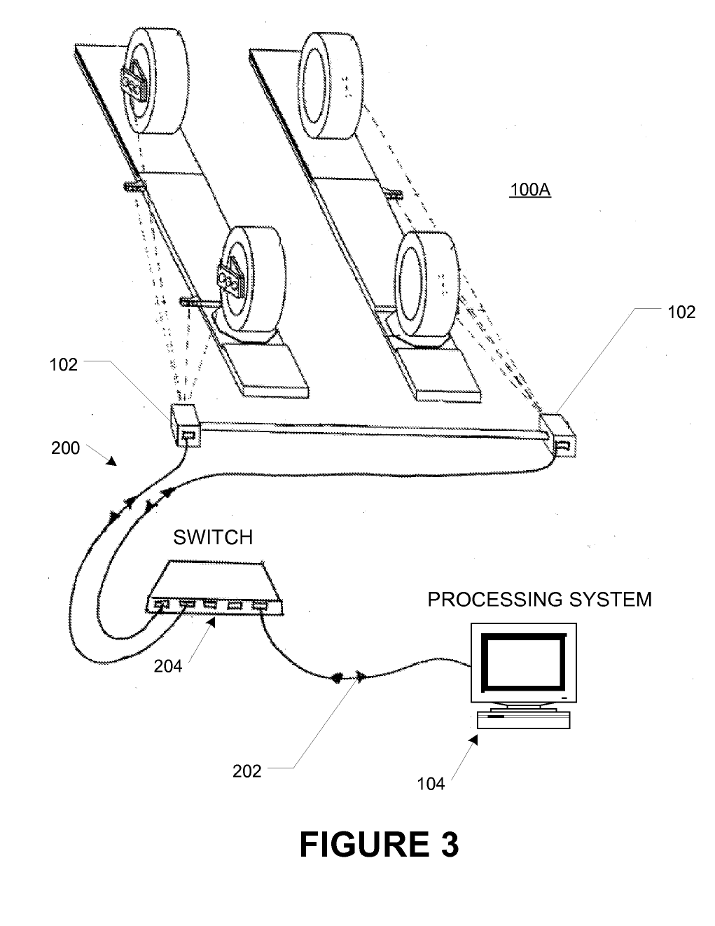

Referring to FIGS. 3-7 an embodiment of the present invention is a machine-vision vehicle wheel alignment system, indicated generally as 100A-100E, which is configured with an improved communication pathway or network 200 for communicating data over a high-speed point-to-point or serial-communication cable pathway or connection 202 between one or more devices such as imaging sensors 102 and at least one system processor 104. The communication pathway or network 200 is backward compatible with slower communication standards, suitable for latency-sensitive traffic, and provides dedicated full-duplex connectivity to eliminate bandwidth sharing between links. Preferably, cable connections 202 utilized by the communication pathway or network 200 are capable of spanning large physical distances without requiring repeaters or suffering significant signal degradation. Switch components 204 may be included to switch between communication pathways or networks 200 to enable the interconnection of multiple devices.

For example, Cat-5e LAN copper cable can be used up to 100 meters and with the use of low cost switches, several devices can be run into the same machine-vision vehicle wheel alignment system. The 100-meter cable length limit allows for greater design flexibility in the placement of imaging sensors 102 than is found on current machine-vision vehicle wheel alignment systems 100A-100E which utilize USB 2.0 cables and which require powered hubs between limited lengths of communication cables.

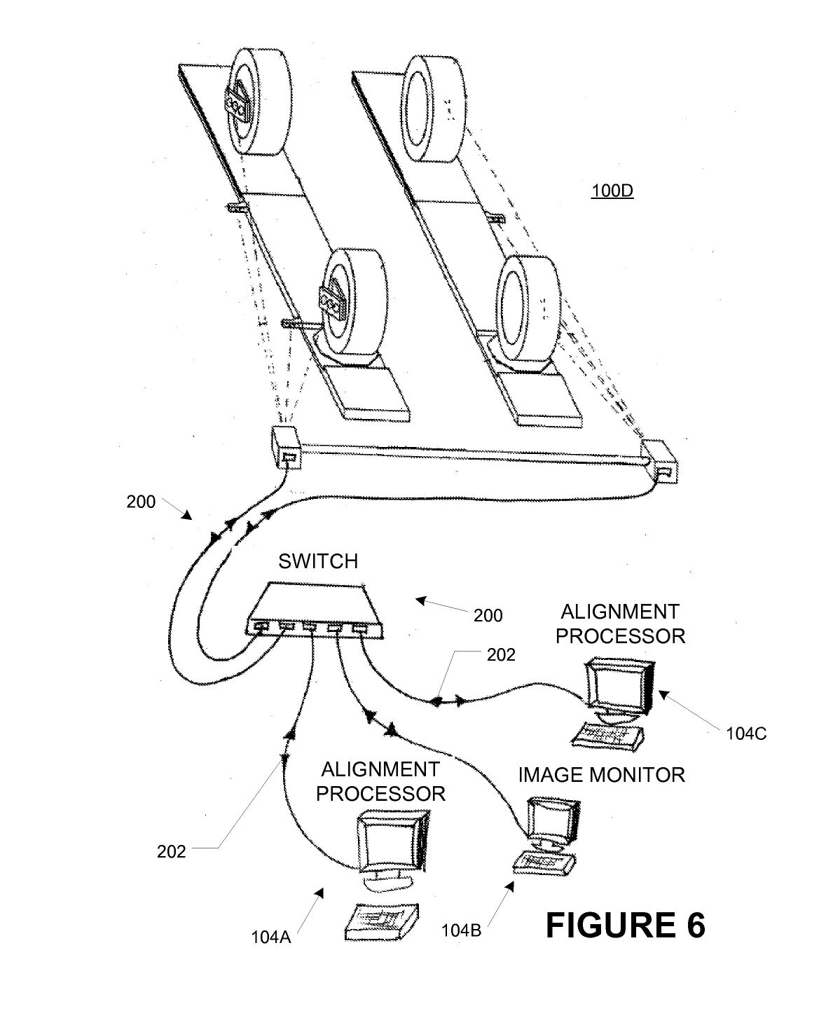

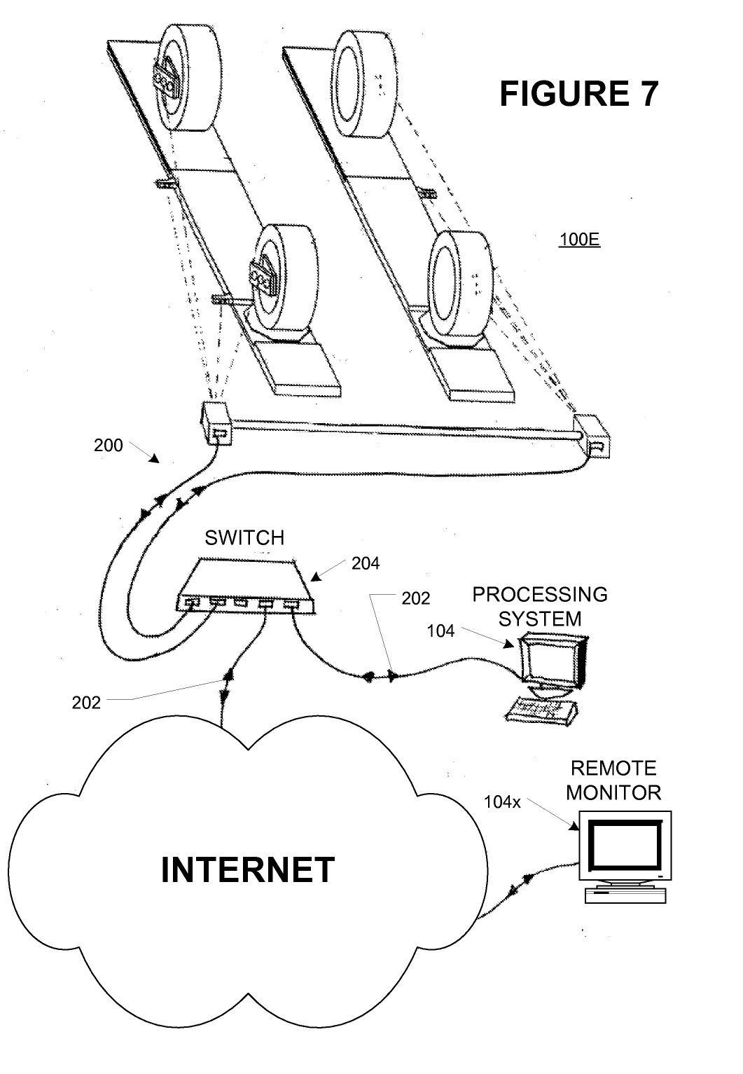

The processing system 104 of the machine-vision vehicle wheel alignment system 100 is enabled to configure individual imaging sensors 102 and to specify data stream channels over the communications pathway or network 200, allowing individual imaging sensors 102 to notify software applications executing on the system processor 104 when specific events occur. While a single software application at the processing system 104 machine-vision vehicle wheel alignment system 100 may control the imaging sensors 102, multiple applications on the same or different processor units 104x can monitor the signals from the imaging sensors, such as shown in FIGS. 6 and 7.

In a first embodiment, such as shown in FIG. 3, a machine-vision vehicle wheel alignment system 100A of the present invention utilizes one or more imaging sensors 102 which are coupled to at least one system processor 104 via a standardized and scalable high-speed communications pathway or network 200 which is compatible with a variety of data communication speeds. The high-speed communications pathway or network 200 is configured to enable the system processor 104 to regulate the operation of the individual imaging sensors 102. Preferably the communications pathway protocols specify discrete data stream channels, regulating the high-speed communications pathway or network 200 to provide a mechanism for the imaging sensors 102 to communicate images and other data to the system processor 104. The images and other data are communicated using defined data types, and are transmitted in a specified manner, thereby enabling compliant devices such as the system processor 104 and imaging sensors 102, to interact via the high-speed communications pathway 200.

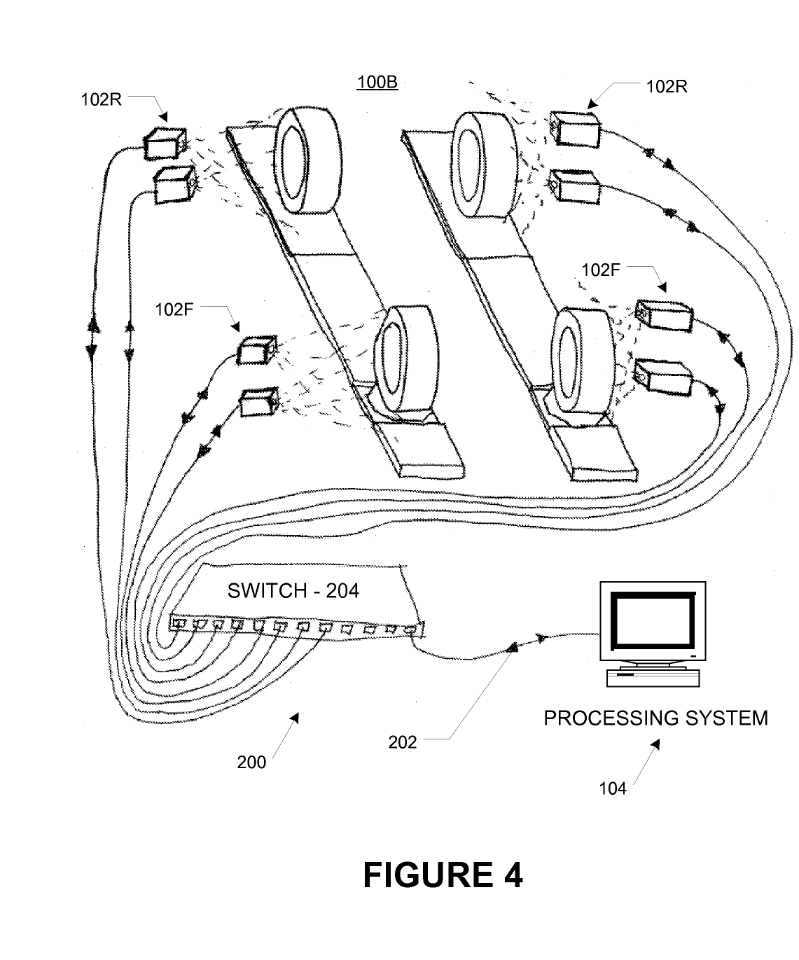

The data communicated from the imaging sensors 102 to the system processor 104 may be time-sensitive, and must be afforded priority when being communicated over a shared high-speed communications pathway or network 200. Accordingly, the high-speed communications pathway or network 200 is configured to permit latency-sensitive traffic, and to prioritize data transmission. The system processor 104 may selectively reduce the bandwidth available to a device coupled to the high-speed communications pathway 200 in order to enable additional devices to share a common network connection. For example, as shown in FIG. 4, information priority for imaging sensors 102R associated with the rear wheels may be reduced while information priority for imaging sensors 102F associated with the front wheels is increased during processing of an alignment steering procedure.

Similarly, to ensure that the vehicle wheel alignment system sensor information is not lost during communication, the high-speed communications pathway or network 200 is configured with extensive error handling and packet re-transmission capabilities. An imaging sensor 102 linked to the high-speed communications pathway or network 200 is preferably configured to report error and/or status information to a vehicle wheel alignment software application executing on the system processor 104, which in turn, can present the information to a service technician in a wheel alignment context sensitive manner. The use of the high-speed communication network 200 enables the tracking of information on the quality of the connection (lost images, corrupt images etc.) between the components such as the imaging sensors 102 and system processor 104. Connection quality information may optionally be used by the vehicle wheel alignment system 100 for error reporting, or for providing specific instructions to an alignment technician on how to improve the operation of the vehicle wheel alignment system 100.

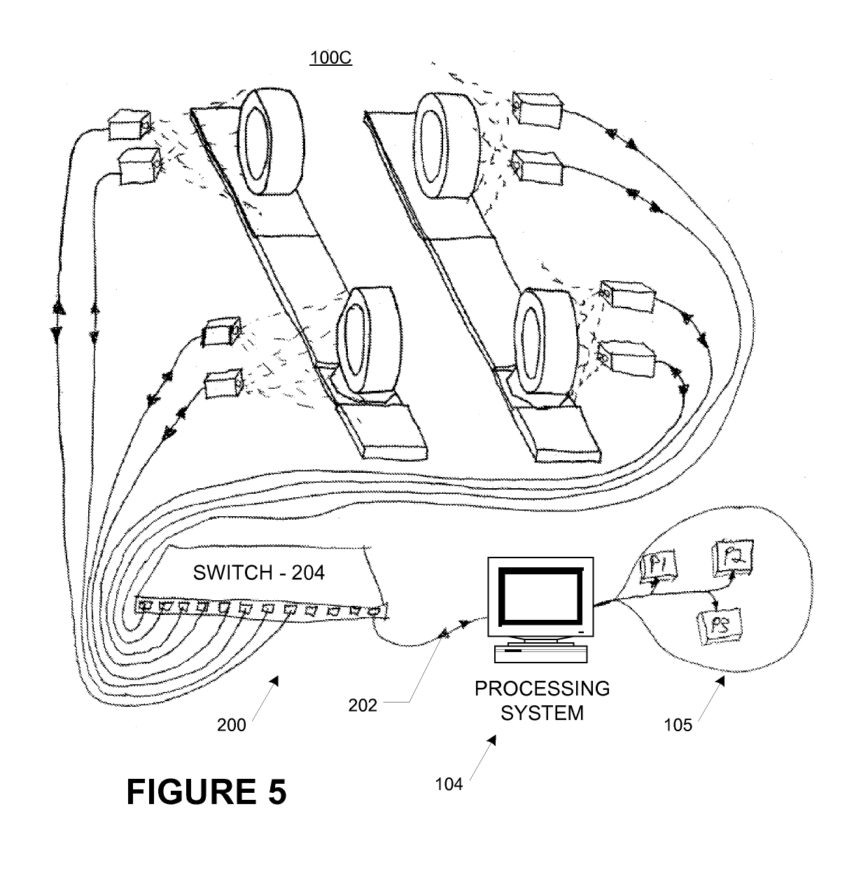

Preferably, the high-speed communication network 200 enables one software application on the processing system 104 to exercise control over the interconnected imaging sensors 102, while permitting other software applications, which may or may not be resident on the same system processor 104, to monitor output signals from the imaging sensor 102. This enables system configurations such as shown in FIGS. 5-7 in which output signals from imaging sensors 102 are received by the system processor 104 and additional processing units 104x which may be remotely located. The controlling software application is considered the “master”, and the imaging sensors 102 are considered the “slave” devices. Command requests are initiated by the controlling software application as single data packets, and acknowledgement messages generated by the imaging sensors 102 are similarly contained in single data packets. The controlling software application must wait for the acknowledgement message from a recipient imaging sensor 102 before sending the next command message. This creates a very basic handshake protocol, with the acknowledgement message providing a feedback to the controlling software application indicating that the recipient imaging sensor 102 has received an issued command via the high-speed communications network 200.

To provide a measure of design flexibility into the machine-vision wheel alignment system 100 of the present invention, it is preferred that the various devices coupled to the high-speed communications network 200, such as the imaging sensors 102, be configured to describe their own characteristics to the communications network 200 (i.e., Plug & Play) so that no additional configuration files or any other “external” descriptions are required for a system processor 104 to configure and use the features of the interconnected devices. This enables imaging sensors 102 from different manufacturers to be compatible or interchangeable in a vehicle wheel alignment system 100 from a software point of view, enabling subsequent designs of imaging sensors 102 to be purchased from third-party suppliers rather than custom built and designed by the original manufacturer of the machine-vision vehicle wheel alignment system 100.

It is further preferred that the high-speed communications network 200 utilize a device compatibility standard which clearly states mandatory elements (things that must be implemented by a device in order to be standard compliant for use with the high-speed communications network 200), optional elements (things that can be implemented and their design/behavior is defined by the compatibility standard) and extended elements (things that are manufacturer defined, and not part of the compatibility standard). Preferably, by conforming to the selected compatibility standard, the functionality of imaging sensors 102 will be modular, so that future imaging sensor products can extend the compatibility standard while an imaging sensor device with only minimal functionality will remain compliant with the high-speed communications network 200. It will be possible to add custom features to a device without violating the standard, for example, data encryption and user authentication.

In one embodiment of the present invention, the high-speed communications network 200 is implemented using a GigE Vision interface standard to provide a communication standard suitable for imaging sensors 102 coupled via local Ethernet networks to one or more system processors 104, 104x as shown in FIGS. 5-7. The GigE Vision interface standard has three main elements.

First, the GigE Vision Control Protocol (GVCP) defines how to control a GigE Vision-compliant device (i.e. imaging sensor 102) and to specify stream channels, providing a mechanism for the devices to send images and other data to the vehicle wheel alignment system processor 104.

Second, the GigE Vision Stream Control Protocol (GVSP) defines data types and describes how images are transmitted over a network 200 using the GigE Vision interface standard.

Third, the GigE Device Discovery mechanism defines how compliant devices, such as imaging sensors 102, obtain IP addresses and how applications control the devices on a network 200.

Within the GigE Vision interface standard, the GVCP allows software applications on the machine-vision vehicle service system processor 104 to configure imaging sensors 102, specify data stream channels, and allows imaging sensors 102 to notify the software applications when a specific event occurs. The GVCP provides support for one software application to control an imaging sensor 102, but also allows many applications to monitor the output signals from the imaging sensor 102.

Within the Internet transport layer protocols, the GVCP runs on top of the User Datagram Protocol (UDP), one of several transport protocols operating at Layer 4 of the traditional seven-layer IP stack. The UDP delivers efficient transfer performance, but does not guarantee data delivery. To address this limitation, GVCP defines mechanisms to guaranty reliable packet transmission and to ensure minimal flow control. The confinement of command and acknowledgement messages to single data packets is one example.

Similar to GVCP, the GVSP also uses the UDP to receive image data, image information, and other data from an imaging sensor 102. The maximum packet size used by GVSP is defined by GVCP, allowing it to be tailored to the requirements of a vehicle service system 100. To avoid IP fragmentation and to ensure data transfer through a local area network (LAN), the vehicle service system's software application must negotiate packet size with each imaging sensor 102. The do-not-fragment bit in the standard IP header can be used to ensure packets remain intact during transmission across the network 200.

One of the advantages of a machine-vision vehicle wheel alignment system 100 utilizing the GigE Vision interface standard to communicate with an imaging sensor 102 is a controlled approach to the rate at which images are acquired by the imaging sensor 102. Current imaging sensors generally acquire images at a rate of approximately 8 frames per second (8 HZ) which is controlled by the vehicle wheel alignment system processor 104, with the alignment system processor 104 instructing each individual image sensor 102 when to acquire an image. Utilizing the GigE Vision interface standard, an alignment system processor 104 of the present invention can instruct an individual imaging sensor 102 at what rate to take images, assume responsibility for processing the resulting images, and control the parameters under which the imaging sensor 102 acquires the images (windowing, exposure, etc.). If the imaging sensor 102 is communicating images over the high-speed communications network 200 faster than the alignment system processor 104 can process them, the imaging sensors 102 can be slowed down in response to a command issued from the alignment system processor 104, or the images may be stored for subsequent processing. This results in improvements in adjustability and controllability, and enables the acquisition of images from the imaging sensors 102 over the high-speed communications network 200 at rates greater than 10 frames per second (10 Hz), and optionally, at streaming video rates of at least 30 frames per second (30 Hz).

An alternate embodiment of the present invention provides a machine-vision vehicle wheel alignment system 100 with one or more imaging sensors 102 and a system processor 104 configured to utilize a GenICam application programming interface (API) standard. The GenICam interface standard can be applied to any number of imaging sensors 102 using various connection options including 1394, USB, and Camera Link. The GenICam interface standard provides a software layer in the imaging sensors 102 for creating a standard set of communication interfaces to enable software applications on the system processor 104 to communicate with the imaging sensors 102 via the communications network 200. The main tasks provided by the GenICam standard are:
GenApi: Configuring the imaging sensor.
Features: Recommended names and types for common features.
TransportLayer: Grabbing images.
DataStream: Interpreting additional data that might be appended to the image.

A machine-vision vehicle wheel alignment system 100 utilizing the GenICam standard facilitates the attachment of imaging sensors 102 from different manufacturers to a single system processor 104. For example, if an imaging sensor manufacturer stops production suddenly, an end-user could purchase a 3^{rd} party camera replacement imaging sensor 102 directly capable of communicating with the alignment system processor 104.

A machine-vision vehicle wheel alignment system 100 of the present invention configured with a high-speed communications network or pathway 200 between one or more imaging sensors 102 and a system processor 104, provides the ability to maximize acquisition of image data during vehicle wheel alignment procedures, and to further process the image data when the data acquisition phase of the procedures is completed. For example, vehicle wheel alignment procedures for determining the “piercing point” on an optical target secured to a vehicle wheel, i.e. the point at which a wheel's axis of rotation passes through the face of the optical target, typically require image over-sampling but are currently restricted by the conventional communication pathway bandwidth between the imaging sensors 102 and the processing system 104. An advantage of utilizing imaging sensors 102 compatible with high-speed communication networks and pathways 200 is that more images may be captured in the same period of time.

For example, when a vehicle wheel steering procedure is started, imaging sensors 102F configured to view the front wheels of a vehicle may be instructed by the processing system 104 to acquire images at a maximum rate. The imaging sensors 102R configured to view the rear wheels may concurrently be instructed by the processing system 104 to acquire images at a slower predetermined rate, such as one image/second (1 Hz). The procedural steps of the steering procedure are carried out to completion, at which point the imaging sensors 102F and 102R are instructed to return to their normal rates of image acquisition. Images acquired during the steering procedure may be stored chronologically, with a time stamp or with a sequence number to identify the order in which they were taken. Conventionally, only a fraction of the images are processed by the vehicle wheel alignment processing system 104 during the steering procedure, leaving the bulk of the processing to be subsequently carried out at a later point in time.

Utilizing a high-speed communications network such as the GigE Vision based imaging system or a GenICam imaging system improves the image processing capability of a vehicle wheel alignment processing system 104, and enables faster processing of the received images, either through distributed processing over the communications network 200 or simultaneous processing and storage, allowing the use of streaming video from the imaging sensors.

An additional example of a vehicle wheel alignment procedure carried out by a machine-vision vehicle wheel alignment system 100, which may benefit from improved image processing capability is a vehicle rolling compensation procedure. Traditionally, a machine-vision vehicle wheel alignment system 100 is configured to track one or more observed objects on the surface of a wheel assembly as the vehicle is rolled a short distance. To do this, a cross product is calculated between the observed object on two or more subsequent images. These cross product calculations are best done with little spatial separation between the position of the wheel assembly in each of the images. During the rolling process, acquired images are processed to determine the relative distance the vehicle has rolled. Once the rolling procedure is completed, all of the acquired images are fully processed to determine cross product calculation, compensation vectors, or piercing points.

Hence, there is a significant advantage to providing a vehicle wheel alignment system 100 with an improved means to acquire images at a high rate of speed, such as by utilizing a GigE Vision compatible configuration of imaging sensors 102 and processing systems 104.

During a rolling compensation procedure, there are a minimum of four image streams for the processing system 104 to receive and process, one associated with each vehicle wheel. These image streams may be transferring image data at a rate in excess of 10 frames per second (10 Hz), and may optionally consist of streaming video data. If stereo images are acquired at each wheel, a total of eight image streams will be available for processing. By utilizing a GigE Vision compatible configuration of imaging sensors 102 and processing systems 104 the image streams may be routed to distributed processors 105 within a single processing system 104, such as shown in FIG. 5, to facilitate the image processing.

The use of a high-speed communication network 200 to link the imaging sensors 102 and system processor 104 of a machine-vision vehicle wheel alignment system 100 facilitates and enables the use of distributed processing of image data over a network. However, in many high-speed networks, where multiple system processors reside within a single network or system, the ability of the system processors and operating systems to scale well for distributed processing in a multi-processor network is generally inhibited by the architecture of the various software applications regulating the interactions between the system processors and the high-speed communication networks. For example, common network protocol stacks, such as the Network Driver Interface Specification (NDIS) 5.1 and earlier versions associated with the Microsoft® Windows® operating system lack the ability to scale well on distributed processing systems because the architecture of the network protocol stack limits receive-protocol processing to a single system processor.

Vehicle alignment processing systems 104 of the present invention may optionally be configured to implement operating system scalable architectures which enable a division of distributed processing tasks, and which include mechanisms for balancing a processing load received from a high-speed communication network 200 across multiple system processors 104x. For example, to improve overall performance of machine-vision vehicle wheel alignment systems which are capable of high-speed image acquisition over communications networks and pathways 200, such as disclosed herein, the system processors may be configured to resolves single-CPU processing issues by implementing Receive Side Scaling (RSS) with the Network Driver Interface Specification (NIDS) 6.0. The NDIS 6.0 is a Microsoft Scalable Networking Initiative technology that enables receive-protocol processing to be balanced across multiple processors within a system, while maintaining in-order delivery of the data. RSS enables parallel Deferred Procedure Calls (DPCs) and supports multiple interrupts in conjunction with the processing system 104. RSS provides the following benefits that directly affect the needs of a machine-vision vehicle wheel alignment system 100:

Parallel execution. Received packets from a single network adapter can be processed concurrently on multiple processing systems 104x, while preserving in-order delivery.

Dynamic load balancing. As system load on the host system processor 104 varies, RSS rebalances the network processing load among available interconnected processing systems 104x. As an example, when a vehicle wheel alignment system is printing a report, a system processor can become very busy with that task. RSS can rebalance the processing load to other system processors 104x on the communications network 100 to accommodate the printing task.

Cache locality. Because packets from a single connection are always mapped to a specific processor 104, data for a particular connection never has to move from one processor's cache to another processor's cache, thereby eliminating cache thrashing and also promoting improved performance.

Send side scaling. Traditional Transmission Control Protocol (TCP) is often limited as to how much data can be sent to a remote processing system 104x. The reasons can include the TCP congestion window, the size of the advertised receive window, or TCP slow-start. When an application tries to send a buffer larger than the size of the advertised receive window, TCP sends part of the data and then waits for an acknowledgment before sending the balance of the data. When the TCP acknowledgement arrives, additional data is sent in the context of the DPC in which the acknowledgement is indicated. Thus, scaled receive processing can also result in scaled transmit processing.

Secure hash. The default generated RSS signature is cryptographically secure, making it much more difficult for malicious remote processing systems 104x to force the vehicle wheel alignment system processor 104 into an unbalanced state. Although the majority of the time a machine-vision vehicle wheel alignment system 100 will have a dedicated network configuration, external connections are increasingly common for internet connectivity, as shown in FIG. 7. A secure hash is therefore a benefit to the machine-vision vehicle wheel alignment system 100.

With data from imaging sensors 102 on a machine-vision vehicle wheel alignment system requiring increased processing, and the likelihood of imaging sensors 102 being incorporated into other types of vehicle service equipment, such as wheel balancers, a need for multiple processors 105 within a single system 100 may arise, as shown in FIG. 5. As part of the overall vehicle service system, the addition of RSS will improve the update rate by reducing the time spent receiving images from an Ethernet connection, and will work to complement image processing systems employing the GigE Vision standard. Without RSS, the data received on an Ethernet connection is limited to being processed by a single processing system 104. The incorporation of RSS into a vehicle service system allows the Ethernet packet receive-processing to scale with the number of available processors in the vehicle service system and increase the update rate of the overall vehicle service system when receiving image data such as streaming video via an Ethernet communications link.

In an alternate embodiment of the present invention, imaging sensors 102 which are operatively coupled to a vehicle service system via a high-speed point-to-point or serial communications pathway 202 over which image data or control signals are communicated, are configured to receive an operational supply of power through the same pathway 202 as the communicated image data and control signals.

The present invention can be embodied in the form of computer-implemented processes and apparatuses for practicing those processes. The present invention can also be embodied in the form of computer program code containing instructions embodied in tangible media, such as floppy diskettes, CD-ROMs, hard drives, or any other computer readable storage medium, wherein, when the computer program code is loaded into, and executed by, an electronic device such as a computer, micro-processor or logic circuit, the device becomes an apparatus for practicing the invention.

The present invention can also be embodied in the form of computer program code, for example, whether stored in a storage medium, loaded into and/or executed by a computer, or transmitted over some transmission medium, such as over electrical wiring or cabling, through fiber optics, or via electromagnetic radiation, wherein, when the computer program code is loaded into and executed by a computer, the computer becomes an apparatus for practicing the invention. When implemented in a general-purpose microprocessor, the computer program code segments configure the microprocessor to create specific logic circuits.

In view of the above, it will be seen that the several objects of the invention are achieved and other advantageous results are obtained. As various changes could be made in the above constructions without departing from the scope of the invention, it is intended that all matter contained in the above description or shown in the accompanying drawings shall be interpreted as illustrative and not in a limiting sense.

1. An improved automotive service system having at least one processing system configured with at least one vehicle service software application, the improvement comprising:
at least one imaging sensor operatively coupled to the at least one processing system via a high-speed communication pathway; and
wherein the at least one processing system is adapted for selective control of an image acquisition rate of said at least one imaging sensor via said high-speed communication pathway.

2. The improved automotive service system of claim 1 wherein said at least one imaging sensor is networked with a plurality of processing systems via said high-speed communication pathways.

3. The improved automotive service system of claim 1 wherein the at least one processing system is configured to establish image acquisition parameters for said at least one imaging sensor.

4. The improved automotive service system of claim 1 wherein said at least one imaging sensor is configured to receive operating power through a connector associated with said high-speed communications pathway.

5. The improved automotive service system of claim 1 wherein said high-speed communication pathway conforms to a GigE Vision interface standard.

6. The improved automotive service system of claim 1 wherein said imaging sensor conforms to a GenICam interface standard.

7. The improved automotive service system of claim 1 wherein said high-speed communication pathway is compatible with an Ethernet network protocol standard.

8. The improved automotive service system of claim 1 wherein said high-speed communication pathway is configured to transfer image data at an image frame rate greater than 10 Hz.

9. An improved vehicle service system having a plurality of processing units configured to receive data packets via an Ethernet communications link, the improvement comprising:
a network interface adapted to scale Ethernet packet receive-processing to the number of available processing units in the vehicle service system.

10. The improved vehicle service system of claim 9 wherein said network interface is configured with receive-side scaling algorithms.

11. The improved vehicle service system of claim 9 wherein said network interface enables parallel deferred procedure calls.

12. The improved vehicle service system of claim 9 wherein said network interface enables multiple interrupts.

13. The improved vehicle service system of claim 9 wherein said network interface is configured to process receive packets from a single network adapter concurrently on said plurality of processing units while preserving in-order delivery.

14. The improved vehicle service system of claim 9 wherein said network interface is configured to balance a network processing load between said plurality of processing units.

15. The improved vehicle service system of claim 9 further including at least one imaging sensor configured to communicate data to said plurality of processing units via the Ethernet communications link; and
wherein said plurality of processing units are each configured with at least one vehicle service software application.

16. The improved vehicle service system of claim 15 wherein the Ethernet communications link conforms to at least one Ethernet-based communications standard including Gigabit Ethernet, 10-Gig Ethernet, and GigE Vision.

17. A method for image acquisition for use with a machine-vision automotive service system having at least one imaging sensor operatively coupled to a processing system configured with at least one vehicle service software application, the improvement comprising:
selecting, responsive to a current vehicle service procedure, an image acquisition rate of the at least one imaging sensor; and
communicating image data from the at least one imaging sensor to the processing system at said selected image acquisition rate during said current vehicle service procedure.

18. The method of claim 17 for image acquisition further including the step of selectively altering a communications bandwidth over a communications pathway between the at least one imaging sensor and the processing system.

19. The method of claim 17 for image acquisition further including the step of selectively altering an information priority setting associated with data communicated to the processing system from the at least one imaging sensor.

20. The method of claim 17 for image acquisition further including the step of communicating data transmission status data from the at least one imaging sensor to the processing system.
